(19) United States
(12) Patent Application Publication
(10) Pub. No.: US 2026/0266567 A1
(43) Pub. Date: Sep. 10, 2026

(54) COOLING DEVICE

(71) Applicant: NIDEC CORPORATION, Kyoto (JP)

(72) Inventors: Takehito TAMAOKA, Kyoto (JP); Takaya OKUNO, Kyoto (JP); Tadahiro KURAMOTO, Kyoto (JP)

(21) Appl. No.: 19/556,007

(22) Filed: Mar. 4, 2026

(30) Foreign Application Priority Data
Mar. 7, 2025 (JP) 2025-036765

(51) Int. Cl. F28F 9/02

(52) U.S. Cl. CPC F28F 9/0256; F28F 2265/00

(57) ABSTRACT

A cooling device includes a joint, a flow pipe, and a first cover. The joint includes a joint body and a first protruding portion. The joint body includes an internal flow path. The first protruding portion protrudes from the joint body, includes an internal flow path, and is fluidly connected to the joint body. The flow pipe is connected to the first protruding portion and is fluidly connected to the joint. The first cover covers an outer circumferential surface of a connection portion between the first protruding portion and the flow pipe.

### CROSS-REFERENCE TO RELATED APPLICATIONS

The present application claims priority under 35 U.S.C. § 119 to Japanese Patent Application No. 2025-036765, filed on Mar. 7, 2025, the entire contents of which are hereby incorporated herein by reference.

### 1. FIELD OF THE INVENTION

Example embodiments of the present disclosure relate to cooling devices.

### 2. BACKGROUND

There are cooling devices that include a joint having an internal flow path through which a refrigerant flows, and a flow pipe that is fluidly connected to the joint.

However, in the cooling devices in which the refrigerant flow pipe is fluidly connected to the joint, stress concentration at a connection portion of the flow pipe with the joint, which may have an adverse effect on the flow pipe.

### SUMMARY

A cooling device according to an example embodiment of the present disclosure includes a joint, a flow pipe, and a first cover. The joint includes a joint body and a first protruding portion. The joint body includes an internal flow path. The first protruding portion protrudes from the joint body, includes an internal flow path, and is fluidly connected to the joint body. The flow pipe is connected to the first protruding portion and is fluidly connected to the joint. The first cover covers an outer circumferential surface of a connection portion between the first protruding portion and the flow pipe.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is an explanatory diagram illustrating a cooling device according to an example embodiment of the present invention.

FIG. 2 is an explanatory diagram illustrating an example of a connection portion between a joint and a flow pipe according to an example embodiment of the present invention.

FIG. 3 is an explanatory diagram illustrating a first modified example of a connection portion between a joint and a flow pipe according to an example embodiment of the present invention.

FIG. 4 is an explanatory diagram illustrating a second modified example of a connection portion between a joint and a flow pipe according to an example embodiment of the present invention.

FIG. 5 is an explanatory diagram illustrating a third modified example of a connection portion between a joint and a flow pipe according to an example embodiment of the present invention.

FIG. 6 is an explanatory diagram illustrating an example of a connection portion between a joint according to an example embodiment of the present invention and a cooler.

FIG. 7 is an explanatory diagram illustrating an example of a fastening portion between a cooling device an example embodiment of the present invention and a bracket.

FIG. 8 is an explanatory diagram illustrating an example of a fastening portion between a cooling device according to an example embodiment of the present invention and an object to be cooled.

FIG. 9 is an explanatory diagram of a cold plate according to an example embodiment of the present invention.

### DETAILED DESCRIPTION

Example embodiments of cooling devices will be described in detail below with reference to the accompanying drawings. Note that the present disclosure is not limited to the example embodiments described below. In the following description, identical components are denoted by the same reference numerals, and redundant description will be omitted.

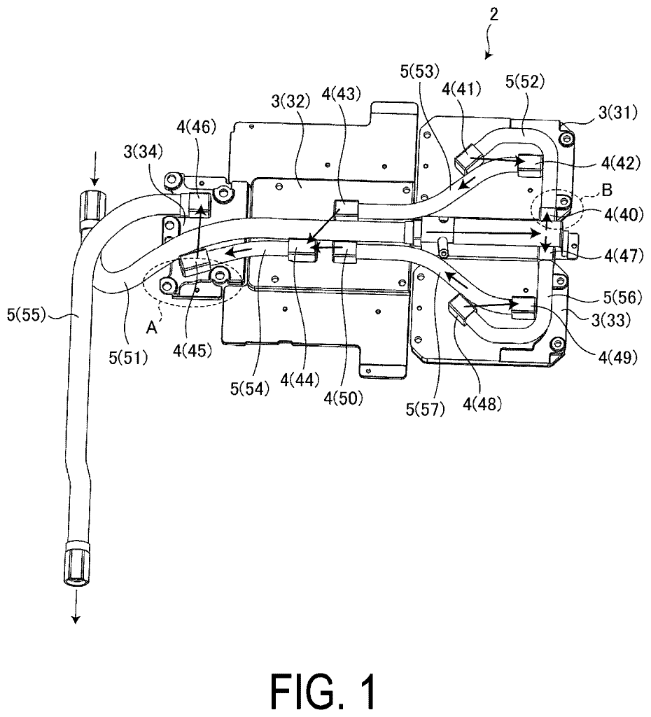

FIG. 1 is an explanatory diagram illustrating a cooling device 2 according to an example embodiment. The cooling device 2 is a device that is attached to an object to be cooled that is a heat source, and cools the object to be cooled. As illustrated in FIG. 1, the cooling device 2 includes multiple (here, four) coolers 3 (31 to 34) and multiple (here, eleven) joints 4 (40 to 50) that are fluidly connected to the coolers 3 (31 to 34). The cooling device 2 further includes flow pipes 5 (51 to 57) that are fluidly connected to the joints 4 (40 to 50).

Note that in the following description, when referring to any one of the multiple coolers 31 to 34, it is referred to as a cooler 3. When referring to any one of the multiple joints 40 to 50, it is referred to as a joint 4. When referring to any one of the multiple flow pipes 5 (51 to 57), it is referred to as a flow pipe 5.

The flow pipes 51 and 55 are fluidly connected to a refrigerant circulation device (not illustrated). Each cooler 3 has an internal flow path through which a refrigerant flows. The refrigerant cooled by the refrigerant circulation device passes through the flow pipe 51 and is supplied to the joints 40 and 47.

The refrigerant supplied to the joint 40 passes through the flow pipe 52 and is supplied from the joint 41 to the internal flow path of the cooler 31. When the refrigerant passes through the internal flow path of the cooler 31, the refrigerant absorbs heat from the object to be cooled, thereby cooling the object to be cooled.

The refrigerant that has passed through the internal flow path of the cooler 31 passes through the joint 42, the flow pipe 53, and the joint 43 in this order, and is supplied to the internal flow path of the cooler 32. When the refrigerant passes through the internal flow path of the cooler 32, the refrigerant absorbs heat from the object to be cooled, thereby cooling the object to be cooled.

The refrigerant that has passed through the internal flow path of the cooler 32 passes through the joint 44, the flow pipe 54, and the joint 45 in this order, and is supplied to the internal flow path of the cooler 34. When the refrigerant passes through the internal flow path of the cooler 34, the refrigerant absorbs heat from the object to be cooled, thereby cooling the object to be cooled. The refrigerant that has passed through the internal flow path of the cooler 34 passes through the joint 46 and is sent from the flow pipe 55 to the refrigerant circulation device. The refrigerant sent to the refrigerant circulation device is cooled by a heat exchanger inside the refrigerant circulation device, and is supplied to the cooling device 2 again via the flow pipe 51.

The refrigerant supplied to the joint 47 passes through the flow pipe 56 and is supplied from the joint 48 to the internal flow path of the cooler 33. When the refrigerant passes through the internal flow path of the cooler 33, the refrigerant absorbs heat from the object to be cooled, thereby cooling the object to be cooled.

The refrigerant that has passed through the internal flow path of the cooler 33 passes through the joint 49, the flow pipe 57, and the joint 50 in this order, and is supplied to the internal flow path of the cooler 32. When the refrigerant passes through the internal flow path of the cooler 32, the refrigerant absorbs heat from the object to be cooled, thereby cooling the object to be cooled.

The refrigerant that has passed through the internal flow path of the cooler 32 passes through the joint 44, the flow pipe 54, and the joint 45 in this order, and is supplied to the internal flow path of the cooler 34. When the refrigerant passes through the internal flow path of the cooler 34, the refrigerant absorbs heat from the object to be cooled, thereby cooling the object to be cooled. The refrigerant that has passed through the internal flow path of the cooler 34 passes through the joint 46 and is sent from the flow pipe 55 to the refrigerant circulation device. The refrigerant sent to the refrigerant circulation device is cooled by a heat exchanger inside the refrigerant circulation device, and is supplied to the cooling device 2 again via the flow pipe 51.

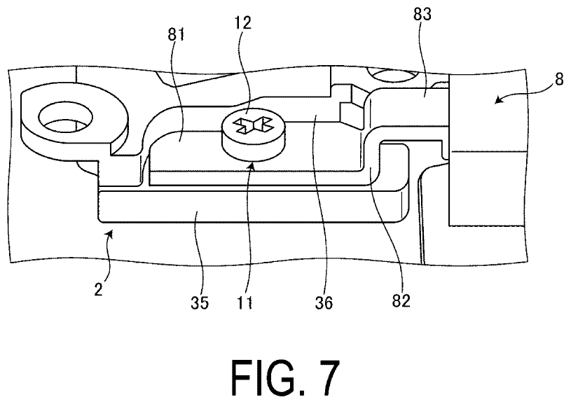

The cooling device 2 is fitted with a bracket (not illustrated) that serves as a support base for fixedly positioning the four coolers 31 to 34 relative to one another. The bracket is fixed, for example, by screws at locations such as a fixing portion of the cooling device 2 indicated by a dashed elliptical frame A in FIG. 1. The structure of the fixing portion of the cooling device 2 indicated by the dashed elliptical frame A will be described below with reference to FIG. 7.

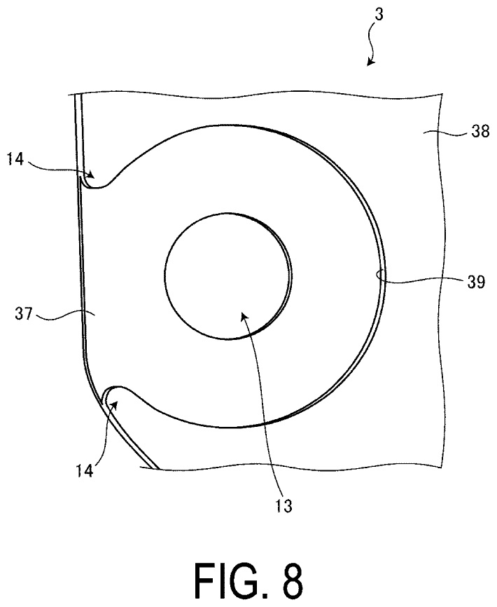

The cooling device 2 is fixed to the object to be cooled by screws at locations such as a fixing portion indicated by a dashed elliptical frame B in FIG. 1. The structure of the fixing portion indicated by the dashed elliptical frame B in FIG. 1 will be described below with reference to FIG. 8.

In this cooling device 2, stress may be concentrated at the connection portion of the flow pipe 5 with the joint 4, which may cause an adverse effect on the flow pipe 5, such as damage at the portion on which the stress is concentrated. Therefore, the cooling device 2 has a configuration that reduces or prevents stress concentration at the connection portion of the flow pipe 5 with the joint 4.

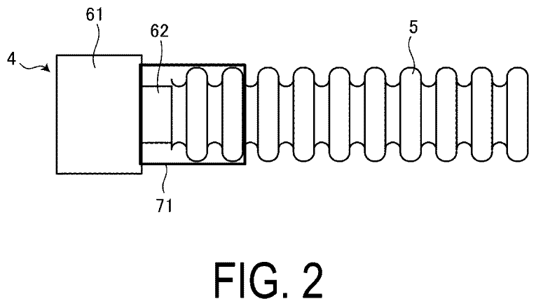

FIG. 2 is an explanatory diagram illustrating an example of a connection portion between the joint 4 and the flow pipe 5 according to an example embodiment of the present invention. As illustrated in FIG. 2, the joint 4 includes a joint body 61 and a first protruding portion 62. The joint body 61 has an internal flow path and is fluidly connected to the cooler 3.

The first protruding portion 62 protrudes from the joint body 61, has an internal flow path, and is fluidly connected to the joint body 61. In one example, the first protruding portion 62 is cylindrical. The flow pipe 5 is connected to the first protruding portion 62 and is fluidly connected to the joint 4.

When a protrusion direction in which the first protruding portion 62 protrudes from the joint body 61 is defined as a first protrusion direction, the flow pipe 5 is connected to the first protruding portion 62 from the first protrusion direction. This facilitates operation to connect the first protruding portion 62 and the flow pipe 5. In one example, the flow pipe 5 may be brazed to the first protruding portion 62 while covering an outer circumferential surface of the first protruding portion 62. That is, the flow pipe 5 may be brazed to the first protruding portion 62 while the first protruding portion 62 is inserted into the flow pipe 5. In another example, the flow pipe 5 may be brazed to the first protruding portion 62 while an outer circumferential surface of the flow pipe 5 is covered with the first protruding portion 62. That is, the first protruding portion 62 may be brazed to the flow pipe 5 while the flow pipe 5 is inserted into the first protruding portion 62.

In one example, the flow pipe 5 is made of metal. Therefore, the flow pipe 5 is stronger than pipes made of resin or rubber. Further, in one example, the flow pipe 5 is a corrugated pipe. Therefore, the flow pipe 5 has improved piping flexibility, and can distribute stress applied to the flow pipe 5 by bending.

In the example illustrated in FIG. 2, the flow pipe 5 is connected to the first protruding portion 62 without being bent from the first protrusion direction, but may be connected to the first protruding portion 62 with the connection portion while the first protruding portion 62 is in a bent state. Note that the flow pipe 5 may be connected to the first protruding portion 62 in a straight state and then bent by applying stress. In the example illustrated in FIG. 2, the first protruding portion 62 protrudes linearly from the joint body 61, but may protrude from the joint body 61 in a bent state.

The cooling device 2 includes a first cover 71 at the connection portion between the joint 4 and the flow pipe 5. The first cover 71 covers the outer circumferential surface of the connection portion between the first protruding portion 62 and the flow pipe 5. Here, the first cover 71 is in contact with both the outer circumferential surface of the first protruding portion 62 and the outer circumferential surface of the flow pipe 5. The first cover 71 reduces or prevents bending or moving of the flow pipe 5 relative to the joint 4, thereby reducing or preventing stress concentration at the connection portion of the flow pipe 5 with the joint 4. The first cover 71 also reduces or prevents stress concentration at the connection portion of the flow pipe 5 with the joint 4 by absorbing stress applied to the connection portion of the flow pipe 5 with the joint 4.

In one example, the first cover 71 has lower rigidity than the joint body 61 and higher rigidity than the flow pipe 5. For example, the Young's modulus of the first cover 71 is smaller than the Young's modulus of the joint body 61 and larger than the Young's modulus of the flow pipe 5. Thus, the first cover 71 can reduce or prevent damage to the flow pipe 5 due to excessive bending while reducing restriction on the range of motion of the flow pipe 5. Here, the first cover 71 has higher rigidity than the flow pipe 5 and has small deflection as a tubular member, thereby reducing or preventing damage to the flow pipe 5 due to excessive bending. Further, since the first cover 71 has lower rigidity than the joint body 61, restrictions on the range of motion of the flow pipe 5 are reduced, improving workability during routing operation of the flow pipe 5.

In addition, an end portion of the first cover 71 on a joint 4 side is in contact with the joint body 61. This allows the first cover 71 to increase an area that can be protected by covering.

In one example, the first cover 71 is a sheet-shaped or tube-shaped member having heat shrinkability. Therefore, after being attached to the connection portion between the joint 4 and the flow pipe 5, the first cover 71 is heated to tightly adhere to the outer circumferential surface of the first protruding portion 62 and the outer circumferential surface of an end portion of the flow pipe 5 on the joint 4 side. Thus, the first cover 71 can reduce or prevent displacement of the flow pipe 5 relative to the first protruding portion 62, and can reduce or prevent leakage of the refrigerant from the connection portion between the joint 4 and the flow pipe 5.

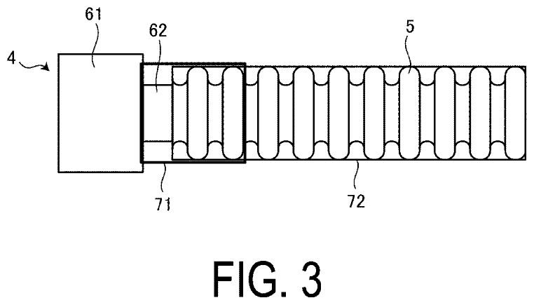

Note that the configuration of the connection portion illustrated in FIG. 2 is an example, and various modifications are possible. Next, a first modified example of a connection portion between a joint 4 and a flow pipe 5 will be described with reference to FIG. 3. FIG. 3 is an explanatory diagram illustrating the first modified example of the connection portion between the joint 4 and the flow pipe 5 according to an example embodiment of the present invention.

As illustrated in FIG. 3, the connection portion between the joint 4 and the flow pipe 5 according to the first modified example differs from the connection portion illustrated in FIG. 2 in that a second cover 72 that covers an outer circumferential surface of the flow pipe 5 is provided, but other configurations are similar to those of the connection portion illustrated in FIG. 2. Thus, the outer circumferential surface of the flow pipe 5 is protected by the second cover 72, so that damage to not only the connection portion between flow pipe 5 and the first protruding portion 62 but also the entirety of the flow pipe 5 is reduced or prevented.

In one example, the second cover 72 has lower rigidity than the first cover 71 and higher rigidity than the flow pipe 5. For example, the Young's modulus of the second cover 72 is smaller than the Young's modulus of the first cover 71 and larger than the Young's modulus of the flow pipe 5. Thus, the second cover 72 can reduce or prevent damage to the flow pipe 5 due to excessive bending while reducing restriction on the range of motion of the flow pipe 5. Here, the second cover 72 has higher rigidity than the flow pipe 5 and has small deflection as a tubular member, thereby reducing or preventing damage to the flow pipe 5 due to excessive bending. Further, since the second cover 72 has lower rigidity than the first cover 71, restrictions on the range of motion of the flow pipe 5 are reduced, improving workability during routing operation of the flow pipe 5. In addition, the second cover 72 covers not only the connection portion between the flow pipe 5 and the joint 4 but also the entirety of the flow pipe 5, thereby reducing or preventing damage to the surface of the flow pipe 5. Even when the second cover 72 covers the entirety of the flow pipe 5, the second cover 72 has lower rigidity than the other members, so it is less likely to reduce workability.

An outer circumferential surface of an end portion of the second cover 72 on a joint 4 side is covered with the first cover 71. As described above, in one example, the first cover 71 is a sheet-shaped or tube-shaped member having heat shrinkability. Therefore, when the first cover 71 covers the second cover 72 and is heated, the first cover 71 adheres tightly to the second cover 72. This reduces or prevents displacement of the second cover 72.

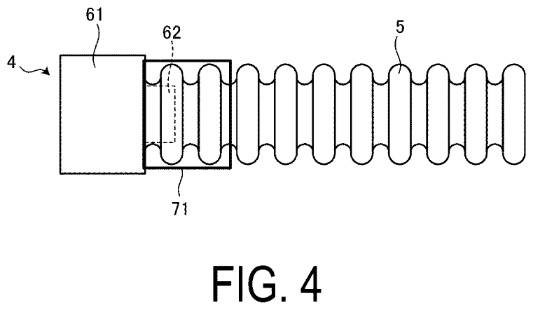

Next, a second modified example of a connection portion between the joint 4 and the flow pipe 5 will be described with reference to FIG. 4. FIG. 4 is an explanatory diagram illustrating the second modified example of the connection portion between the joint 4 and the flow pipe 5 according to an example embodiment of the present invention.

As illustrated in FIG. 4, the connection portion according to the second modified example differs from the connection portion illustrated in FIG. 2 in that an end portion of the flow pipe 5 on the joint 4 side is in contact with the joint body 61, but other configurations are similar to those of the connection portion illustrated in FIG. 2. This increases the contact area between the flow pipe 5 and the joint 4, thereby improving fixing strength of the flow pipe 5 to the joint 4.

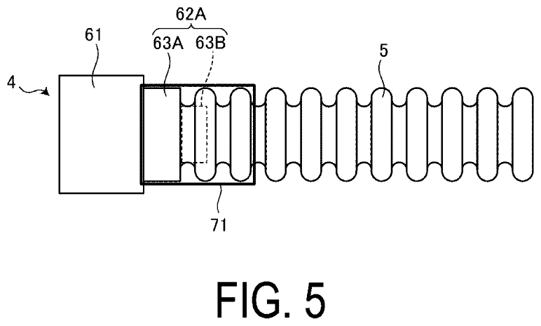

Next, a third modified example of a connection portion between the joint 4 and the flow pipe 5 will be described with reference to FIG. 5. FIG. 5 is an explanatory diagram illustrating the third modified example of the connection portion between the joint 4 and the flow pipe 5 according to an example embodiment of the present invention.

As illustrated in FIG. 5, a first protruding portion 62A according to the third modified example includes a tubular root portion 63A and a tubular tip portion 63B. The root portion 63A protrudes from the joint body 61 in a first protrusion direction. The tip portion 63B protrudes in the first protrusion direction from at least part of the root portion 63A, and has a diameter smaller than a diameter of the root portion 63A.

The first protrusion direction here is a direction from a base end of the first protruding portion 62A connected to the joint body 61 toward a tip of the first protruding portion 62A. The flow pipe 5 is fluidly connected to the tip portion 63B of the first protruding portion 62A.

In the example illustrated in FIG. 5, the root portion 63A and the tip portion 63B are arranged concentrically with the joint body 61 when viewed in an axial direction of an internal flow path. Note that in the example illustrated in FIG. 5, the root portion 63A and the tip portion 63B are arranged linearly in the first protrusion direction, but at least one of the root portion 63A and the tip portion 63B may be bent.

A first cover 71 according to the third modified example covers an outer circumferential surface of the root portion 63A. At this time, a gap is formed between the first cover 71 and an end portion of the flow pipe 5 on a joint 4 side. This reduces or prevents contact between the first cover 71 and the end portion of the flow pipe 5 on the joint 4 side.

An end portion of the flow pipe 5 on the joint 4 side is in contact with the root portion 63A. This increases a contact area between the flow pipe 5 and the first protruding portion 62A, and the contact area between the flow pipe 5 and the first protruding portion 62A is also increased due to contact between the flow pipe 5 and the root portion 63A, thereby improving the fixing strength of the flow pipe 5. Further, by reducing or preventing contact of metal processing marks with the first cover 71, damage to the first cover 71 can be reduced or prevented.

The first cover 71 and the second cover 72 are made of an insulating material. This provides insulation to the flow pipe 5, which is made of a metal material, thereby preventing unexpected short circuits from occurring via the flow pipe 5.

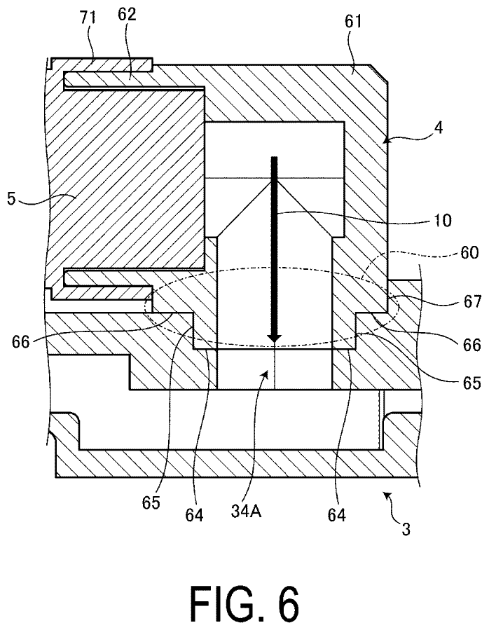

Next, a configuration of a connection portion between the joint 4 according to an example embodiment of the present invention and the cooler 3 will be described with reference to FIG. 6. FIG. 6 is an explanatory diagram illustrating an example of the connection portion between the joint 4 according to an example embodiment of the present invention and the cooler 3. Note that in FIG. 6, an insertion direction of the joint 4 into the cooler 3 is indicated by a thick straight arrow.

As illustrated in FIG. 6, the joint 4 includes an insertion portion 60 that is inserted into an opening portion 34A, which serves as an inlet or outlet for the refrigerant in the cooler 3. The insertion portion 60 is inserted into the opening portion 34A, and, in one example, is brazed to the opening portion 34A to fluidly connect to the cooler 3.

A contact surface between the insertion portion 60 and the opening portion 34A includes a first surface 64 parallel to a plane perpendicular to the insertion direction of the insertion portion 60 (see the thick straight arrow), and a tubular second surface 65 extending from an outer periphery of the first surface 64 toward the joint body 61 in a direction parallel to the insertion direction of the insertion portion 60. That is, the contact surface between the insertion portion 60 and the opening portion 34A is stepped.

This improves the bonding strength between the joint 4 and the cooler 3 when brazing the insertion portion 60 and the opening portion 34A, compared to, for example, when the contact surface between the insertion portion 60 and the opening portion 34A is a simple cylindrical surface. Further, the joint 4 can be easily positioned relative to the cooler 3.

The contact surface between the insertion portion 60 and the opening portion 34A further includes a third surface 66 and a fourth surface 67. The third surface 66 extends from an end portion of the second surface 65 on a joint body 61 side to the outside in a radial direction of the opening portion 34A and is parallel to a plane perpendicular to the insertion direction of the insertion portion 60. The fourth surface 67 extends from at least part of the third surface 66 toward the joint body 61 in a direction parallel to the insertion direction of the insertion portion 60.

That is, the contact surface between the insertion portion 60 and the opening portion 34A is partially stepped with two steps. This further increases the contact area when brazing the insertion portion 60 and the opening portion 34A, further improving the bonding strength between the joint 4 and the cooler 3. In the joint 4 illustrated in FIG. 6, the joint body 61 is bent in an L-shape from an insertion direction of the flow pipe 5 toward the insertion portion 60 in a side view, but the joint body 61 does not have to be bent. That is, the joint body 61 may have a shape in which the insertion direction of the flow pipe 5 and the insertion direction of the insertion portion 60 are aligned in a straight line.

Next, the structure of a fastening portion between a cooling device 2 according to an example embodiment of the present invention and a bracket 8 will be described with reference to FIG. 7. FIG. 7 is an explanatory diagram illustrating an example of the fastening portion between the cooling device 2 according to an example embodiment of the present invention and the bracket 8. FIG. 7 illustrates a portion of the cooling device 2 within a dashed elliptical frame A illustrated in FIG. 1.

As illustrated in FIG. 7, the bracket 8 is fixed to the cooling device 2 by a screw 12. The bracket 8 includes a plate portion 81 having a screw hole 11 formed therein into which the screw 12 is screwed, a rising portion 82 rising from one end of the plate portion 81 in a direction perpendicular to the plate portion 81, and a plane portion 83 extending in a direction parallel to a main surface of the plate portion 81 from one end portion of the rising portion 82 on a side opposite to the plate portion 81 side.

On the other hand, the cooling device 2 includes a planar abutment portion 35 that abuts against the plate portion 81 of the bracket 8. A screw hole into which the screw 12 is screwed is formed in the abutment portion 35. Further, the cooling device 2 includes a wall portion 36 extending from the abutment portion 35 in a direction parallel to a rising direction of the rising portion 82 around the plate portion 81 of the bracket 8 abutting against the abutment portion 35, excluding a portion where the rising portion 82 is provided and a portion that forms an outer periphery of the cooling device 2. Thus, since the wall portion 36 is not provided near the rising portion 82, the fixing strength of the cooling device 2 to the bracket 8 can be improved by increasing the contact area between the plate portion 81 and the abutment portion 35.

The cooling device 2 and the bracket 8 are provided with fastening portions at multiple locations, each having a similar structure to the structure illustrated in FIG. 7. This increases the contact area between the bracket 8 and the cooling device 2, thereby reducing or preventing occurrence of rattling after the bracket 8 and the cooling device 2 are fixed together with the screws 12. Further, since the plate portion 81 of the bracket 8 and the fixing screw 12 are accommodated in a space surrounded by the abutment portion 35 and the wall portion 36 of the cooling device 2, interference of a screw head with other members is reduced or prevented.

Next, the structure of a fastening portion between the cooling device 2 according to an example embodiment of the present invention and the object to be cooled will be described with reference to FIG. 8. FIG. 8 is an explanatory diagram illustrating an example of the fastening portion between the cooling device 2 according to an example embodiment of the present invention and the object to be cooled. FIG. 8 illustrates a rear view of a portion of the cooling device 2 within a dashed elliptical frame B illustrated in FIG. 1.

As illustrated in FIG. 8, the cooling device 2 includes, at a periphery thereof, a thin portion 37 that is circular in a plan view and in which a screw hole 13 is formed. The screw hole 13 is located at the center of the thin portion 37. Note that the object to be cooled to which the cooling device 2 is attached has a screw hole provided at a position corresponding to the position of the screw hole 13.

The cooling device 2 is fixed to the object to be cooled by screwing a screw into the screw hole 13 while the screw hole 13 is aligned with the screw hole in the object to be cooled. The cooling device 2 is provided with fastening portions at multiple locations, each having a similar structure to the structure illustrated in FIG. 8.

The cooling device 2 includes a wall portion 39 that is at least longer than a semicircle of a circular outer periphery of the thin portion 37 in a plan view, and that extends in a thickness direction of the thin portion 37 from an outer periphery excluding a portion forming the outer periphery of the cooling device 2. The cooling device 2 further includes a thick portion 38 extending in a radial direction of the thin portion 37 from one end portion of the wall portion 39 opposite to the thin portion 37.

Thus, the cooling device 2 includes the thick portion 38 that surrounds the outer periphery of the thin portion 37, which is circular in a plan view and is at least longer than a semicircle, and the thick portion 38 includes sharp protruding portions 14 along the outer periphery of the thin portion 37, which is circular in a plan view. This improves the mechanical strength of the cooling device 2 around the screw hole 13.

Furthermore, since the thick portion 38 is not provided at the outer periphery of the cooling device 2, the screw hole 13 can be positioned as close as possible to the periphery of the cooling device 2. This allows the cooling device 2 to be fixed to the object to be cooled at multiple positions as close as possible to the periphery of the cooling device 2, thereby improving the accuracy of the position of the cooling device 2 relative to the object to be cooled.

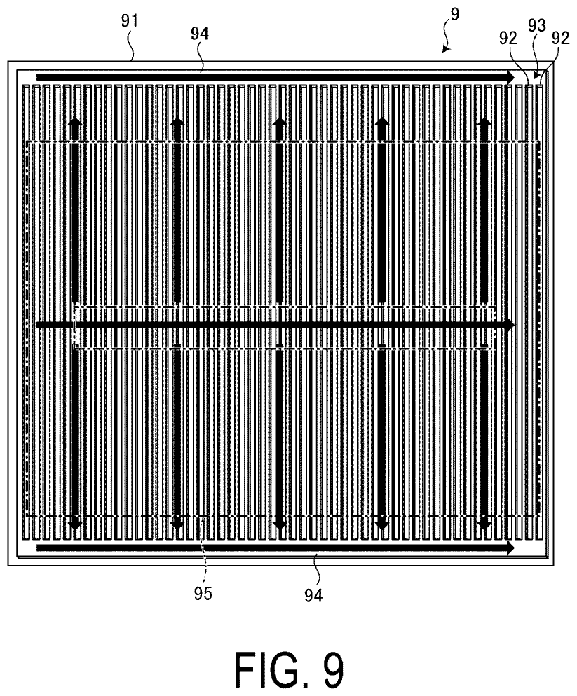

Next, a cold plate 9 according to an example embodiment of the present invention will be described with reference to FIG. 9. FIG. 9 is an explanatory diagram of the cold plate 9 according to an example embodiment of the present invention. The cold plate 9 is provided in each cooler 3 and forms part of the internal flow path for the refrigerant in the cooler 3. FIG. 9 illustrates a surface of the cold plate 9 facing the internal flow path of the cooler 3.

As illustrated in FIG. 9, the cold plate 9 is a plate-shaped member that is rectangular in a plan view. In one example, the cold plate 9 is formed of a material having high thermal conductivity such as copper. The cold plate 9 includes a wall portion 91 placed around a periphery thereof in a frame shape in a plan view. In the cold plate 9, an inner area surrounded by the wall portion 91 forms an internal flow path for the refrigerant.

The cold plate 9 includes multiple fins 92 arranged on a surface facing the internal flow path for the refrigerant. The multiple fins 92 extending in a first direction are arranged side by side in a direction orthogonal to the first direction. The cold plate 9 has gaps 94 through which the refrigerant flows in the wall portion 91 facing both ends of each fin 92. The gaps 94 extend in a second direction, which is an arrangement direction of the fins 92. A flat lid portion 95 that defines the flow path for the refrigerant is placed above the fins 92. The lid portion 95 has a window portion at the center thereof, which does not cover the top of the fins 92. In one example, the window portion is rectangular in shape, with the second direction as a longitudinal direction thereof and the first direction as a transverse direction thereof.

In FIG. 9, directions in which the refrigerant flows are indicated by thick straight arrows. The refrigerant supplied to the internal flow path of the cooler 3 flows in from one end side of the cold plate 9 in the second direction, flows toward another end side in the second direction, and simultaneously flows through flow paths 93 between the fins 92 toward the gaps 94 formed in the wall portion 91. Thereafter, the refrigerant flows through the gaps 94 from the one end side to the other end side in the second direction and flows out of the cooler 3.

Here, when the gaps 94 are not provided, the refrigerant flows into the cold plate 9 from one end in the second direction, and then flows toward the other end in the second direction while passing over the fins 92 located below the window portion not covered by the lid portion 95. In this case, the flow path resistance of the refrigerant increases.

In contrast, the cold plate 9 has the gaps 94 in the wall portion 91 facing both ends of each fin 92, so that the refrigerant can flow from the flow paths 93 between the fins 92 through the gaps 94 toward the other end in the second direction. Thus, the cold plate 9 can reduce the flow path resistance. At this time, part of the refrigerant can flow through the upper region of the fins 92 below the window portion that is not covered with the lid portion 95.

The following supplementary notes are further disclosed regarding the example embodiments including Examples 1 to n described above.

(1)

A cooling device including a joint including a joint body including an internal flow path, and a first protruding portion protruding from the joint body, including an internal flow path, and fluidly connected to the joint body, a flow pipe connected to the first protruding portion and fluidly connected to the joint, and a first cover to cover an outer circumferential surface of a connection portion between the first protruding portion and the flow pipe.

(2)

The cooling device according to (1), in which the first cover has lower rigidity than the first protruding portion and higher rigidity than the flow pipe.

(3)

The cooling device according to (1) or (2), in which the flow pipe is a corrugated pipe made of metal.

(4)

The cooling device according to any one of (1) to (3), in which an end portion of the first cover on a joint side is in contact with the joint body.

(5)

The cooling device according to any one of (1) to (4), including a second cover to cover an outer circumferential surface of the flow pipe, in which the second cover has lower rigidity than the first cover and higher rigidity than the flow pipe.

(6)

The cooling device according to (5), in which an outer circumferential surface of an end portion of the second cover on a joint side is covered with the first cover.

(7)

The cooling device according to any one of (1) to (6), in which an end portion of the flow pipe on a joint side is in contact with the joint body.

(8)

The cooling device according to any one of (1) to (7), in which the first protruding portion includes a root portion having a tubular shape protruding from the joint body, and a tip portion having a tubular shape protruding from at least a portion of the root portion and having a smaller diameter than the root portion, and the first cover covers an outer circumferential surface of the root portion.

(9)

The cooling device according to (8), in which an end portion of the flow pipe on a joint side is in contact with the root portion.

(10)

The cooling device according to (5) or (6), in which the first cover and the second cover are made of an insulating material.

(11)

The cooling device according to any one of (1) to (10), in which the first protruding portion protrudes from the joint body in a first protrusion direction, and the flow pipe is connected to the first protruding portion from the first protrusion direction.

(12)

The cooling device according to any one of (1) to (11), in which the joint includes an insertion portion that protrudes from the joint body and is fluidly connected to a cooler by being inserted into an opening portion of the cooler, and a contact surface between the insertion portion and the opening portion includes a first surface that is or parallel or substantially parallel to a plane perpendicular to an insertion direction of the insertion portion, and a second surface having a tubular shape that extends from an outer periphery of the first surface toward the joint body in a direction parallel or substantially parallel to the insertion direction.

(13)

The cooling device according to (12), in which the contact surface between the insertion portion and the opening portion further includes a third surface extending from an end portion of the second surface on a joint body side to the outside in a radial direction and parallel or substantially parallel to a plane perpendicular to the insertion direction, and a fourth surface extending from at least part of the third surface toward the joint body in a direction parallel or substantially parallel to the insertion direction.

Further effects and modified examples can be easily derived by those skilled in the art. Therefore, the broader aspects of the present disclosure are not limited to the specific details and representative example embodiments shown and described above. Accordingly, various modifications may be made without departing from the spirit or scope of the general inventive concept as defined by the appended claims and their equivalents.

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cooling device comprising:
a joint including:
a joint body including an internal flow path; and
a first protruding portion protruding from the joint body, including an internal flow path, and fluidly connected to the joint body;
a flow pipe connected to the first protruding portion and fluidly connected to the joint; and
a first cover to cover an outer circumferential surface of a connection portion between the first protruding portion and the flow pipe.

2. The cooling device according to claim 1, wherein the first cover has lower rigidity than the first protruding portion and higher rigidity than the flow pipe.

3. The cooling device according to claim 1, wherein the flow pipe is a corrugated pipe made of metal.

4. The cooling device according to claim 1, wherein an end portion of the first cover on a joint side is in contact with the joint body.

5. The cooling device according to claim 1, further comprising:
a second cover to cover an outer circumferential surface of the flow pipe; wherein
the second cover has lower rigidity than the first cover and higher rigidity than the flow pipe.

6. The cooling device according to claim 5, wherein an outer circumferential surface of an end portion of the second cover on a joint side is covered with the first cover.

7. The cooling device according to claim 1, wherein an end portion of the flow pipe on a joint side is in contact with the joint body.

8. The cooling device according to claim 1, wherein the first protruding portion includes a root portion having a tubular shape protruding from the joint body, and a tip portion having a tubular shape protruding from at least a portion of the root portion and having a smaller diameter than the root portion; and
the first cover covers an outer circumferential surface of the root portion.

9. The cooling device according to claim 8, wherein an end portion of the flow pipe on a joint side is in contact with the root portion.

10. The cooling device according to claim 5, wherein the first cover and the second cover are made of an insulating material.

11. The cooling device according to claim 1, wherein
the first protruding portion protrudes from the joint body in a first protrusion direction; and
the flow pipe is connected to the first protruding portion from the first protrusion direction.

12. The cooling device according to claim 1, wherein
the joint includes an insertion portion that protrudes from the joint body and is fluidly connected to a cooler by being inserted into an opening portion of the cooler; and
a contact surface between the insertion portion and the opening portion includes a first surface that is parallel or substantially parallel to a plane perpendicular to an insertion direction of the insertion portion, and a second surface having a tubular shape that extends from an outer periphery of the first surface toward the joint body in a direction parallel or substantially parallel to the insertion direction.

13. The cooling device according to claim 12, wherein the contact surface between the insertion portion and the opening portion further includes:
a third surface extending from an end portion of the second surface on a joint body side to the outside in a radial direction and parallel or substantially parallel to a plane perpendicular to the insertion direction; and
a fourth surface extending from at least a portion of the third surface toward the joint body in a direction parallel or substantially parallel to the insertion direction.
